(19) United States
(12) Patent Application Publication
(10) Pub. No.: US 2014/0149818 A1
(43) Pub. Date: May 29, 2014

(54) DIAGNOSTIC TESTING FOR A DOUBLE-PUMPED MEMORY ARRAY

(71) Applicant: INTERNATIONAL BUSINESS MACHINES CORPORATION, (US)

(72) Inventors: Chad A. Adams, Byron, MN (US); Derick G. Behrends, Rochester, MN (US); Todd A. Christensen, Rochester, MN (US); Elizabeth L. Gerhard, Rochester, MN (US); Michael W. Harper, Round Rock, TX (US); Jesse D. Smith, Rochester, MN (US)

(73) Assignee: INTERNATIONAL BUSINESS MACHINES CORPORATION, Armonk, NY (US)

(21) Appl. No.: 13/786,629

(22) Filed: Mar. 6, 2013

Related U.S. Application Data
(63) Continuation of application No. 13/686,414, filed on Nov. 27, 2012.

(51) Int. Cl. G01R 31/3177

(52) U.S. Cl. CPC G01R 31/3177
USPC 714/733

(57) ABSTRACT

A semiconductor chip and method for diagnostic testing of combinational logic in a logic and array system including Logic Built in Self Test (LBIST) diagnostics are provided. The semiconductor chip includes a logic and array system, an LBIST system, a clocking module, and an addressing module. The method for diagnostic testing includes providing an initialization pattern to an array in the logic and array system, applying a diagnostic control setup, and running the diagnostic test. The diagnostic control setup includes firing a clock every diagnostic test clock cycle and selecting an address from a subset of an address space.

### CROSS-REFERENCE TO RELATED APPLICATIONS

This application is a continuation of co-pending U.S. patent application Ser. No. 13/686,414, filed Nov. 27, 2012. The aforementioned related patent application is herein incorporated by reference in its entirety.

### TECHNICAL FIELD

This disclosure relates generally to the data processing field, and more particularly, relates to a semiconductor chip and a method for diagnostic testing of combinational logic in a logic and array system.

### BACKGROUND

Array Built in Self Test (ABIST) and Logic Built in Self Test (LBIST) constitute two methods used to test integrated circuits. ABIST tests integrated circuits that make up the functional operation of an array such as the array macro and logic used to access the array such as the address, data, and control logic. LBIST tests integrated circuits that make up the functional operation of the logic minus the array cells such as testing AC coverage of logic and latches not covered by ABIST.

For LBIST, typically random patterns are scanned into banks of latches surrounding functional logic circuits. The logic is then functionally clocked and the capture latches are scanned out. The data is compressed and the results are compared with a signature to tell if any AC or DC defects exist. LBIST in this manner is a very well understood and inexpensive way to AC and DC test integrated circuits.

### SUMMARY

In an embodiment, this disclosure relates to a semiconductor chip for diagnostic testing of combinational logic in a logic and array system. The semiconductor chip includes a logic and array system, a Logic Built in Self Test (LBIST) system, a clocking module, and an addressing module. The logic and array system may have a series circuit path through a combinational logic and a data path through an array of the logic and array system. An array in the logic and array system may have a plurality of address inputs. The LBIST system may test the combinational logic in the logic and array system. The clocking module may fire every LBIST clock cycle. A read clock pulse and a write clock pulse may occur every cycle. The addressing module may select an address from a subset of an address space during LBIST testing. The subset of the address space may always be the same address. Aspects may assist the diagnostic test accurately predict data passing through the array.

In an embodiment, this disclosure relates to a method for diagnostic testing of combinational logic in a logic and array system. The method includes providing an initialization pattern to an array in the logic and array system, applying a diagnostic control setup, and running the diagnostic test. The diagnostic control setup includes firing a clock every diagnostic test clock cycle and selecting an address from a subset of an address space. The diagnostic testing may be LBIST testing.

### BRIEF DESCRIPTION OF THE DRAWINGS

FIG. 1A illustrates a prior art circuit path for implementing ABIST testing techniques with a latch-bounded array;

FIGS. 1B and 1C are prior art diagrams illustrating respective circuit paths including an array and logic for implementing testing techniques of ABIST tests for a partial AC path, and LBIST diagnostics for a full AC path;

FIG. 1D illustrates a prior art high level diagram for an LBIST subsystem;

FIG. 2 shows an exemplary computer test system for implementing testing of circuit paths including arrays including LBIST diagnostics according to an embodiment;

FIG. 3 is a block diagram illustrating a computer program product according to an embodiment;

FIGS. 4A, 4B, and 4C depict diagrams illustrating exemplary clocking, addressing, and read/write control modules according to an embodiment;

FIG. 5 depicts a logic and array system according to an embodiment;

FIGS. 6A and 6B depict logic and array systems according to embodiments;

FIG. 7 is a flow chart illustrating exemplary phases for testing an array and logic including LBIST diagnostics according to an embodiment;

FIG. 8 shows a diagram of an example design flow according to an embodiment.

### DETAILED DESCRIPTION

In testing integrated circuits, diagnostic testing techniques such as Array Built in Self Test (ABIST) and Logic Built in Self Test (LBIST) are used to test arrays and logic elements. It is desirable to be able to test the full latch-to-latch paths that are used in the chip function at the same clock rate that will be used in the system application. If the circuits are tested at a slower clock rate or part of the functional path is bypassed, then delay defects could exist that would not be caught by testing but result in a failing chip when exercised in the system. This can be an expensive stage to find and screen-out failing parts.

In some cases static random-access memory (SRAM) arrays are designed to be latch-bounded. In this situation latches exist at all the address and data input pins and latches at the data output pins. The array typically would have one clock cycle to perform a read access and have the data captured in the output latch. The data outputs would be launched out of the array on the subsequent cycle. In other cases, arrays do not have an output latch and logic is placed after the array data outputs and downstream capture latches. As such, knowing the location of logic relative to the array assists in grasping a full understanding of diagnostic testing. The term upstream logic stands for logic feeding into an array, or logic located on a circuit path before an array. The term downstream logic stands for logic fed by an array, or logic located on a circuit path after an array.

ABIST is mostly designed to test the array macro and logic used to access the array such as the address, data, and control logic. If the array is latch-bounded, ABIST uses the same latches as would be used in functional operation. If the array is not latch-bounded, observation latches may need to be used in place of functional latches in upstream logic or downstream logic or both. This leaves for LBIST the task of getting AC coverage of logic and latches that ABIST does not cover.

In an LBIST system, latches within a device under test may be connected with scan chains interposed between levels of a functional logic of the device. A Pseudo-Random Pattern Generator (PRPG) may be used to generate random patterns of bits. Such bits of data may be shifted and stored in the scan chains during a scan shift phase. During a functional phase, the data may be propagated through the functional logic to a subsequent scan chain. The data may then be scanned out of the subsequent scan chain and compressed to reduce storage through use of a Multiple Input Signature Register (MISR). The test loop may be repeated thousands of times with results of each test loop being combined in some manner with the results of previous test loops. After scheduled test loops have been completed, final results or signatures from the test loops may be compared to final results or signatures generated by simulation or a device known to operate properly. Based upon such comparison, it may be determined whether the device under test operates properly. If the MISR signature fails to match the expected signature, one or more faults may be assumed in the logic.

Matching access of the array with a real write or read represents an important and challenging aspect of AC testing. Arrays present a challenge for running LBIST by acting as a block to testing downstream logic and sometimes upstream logic. Two methods exist in the art using LBIST to test upstream logic feeding directly into an array and downstream logic fed by an array. Write-around may include array control logic allowing data to be sent around the array, to the output latches or through logic, and then to the output latches. Write-through may include array control logic simultaneously writing data to the array to be stored at a physical address and driving the read circuitry with identical data to show on the array output. Both methods depend on getting the exact access time for the read correct.

Both write-around and write-through present an additional difficulty for timing since a separate Design For Test (DFT) path for data then exists. If the read data comes out of the array and into logic before being latched, then a need may exist to place a capture latch as close as possible to the array. Since the timing for the read access is not the same as a read to this capture latch, one can get an AC or DC defect that is missed by LBIST. Also, the chance of a race condition on a path going around the array exists. The possibility of updating the test weighting is known in the art, but this may require rescanning the array. Rescanning may cause extra LBIST patterns to be generated to meet test coverage. Further, setting all the address locations in the array will take up more tester time for the LBIST patterns. On a two-port SRAM, where the array may perform a read and a write in one cycle, these difficulties become even more prevalent because the read access is more timing critical.

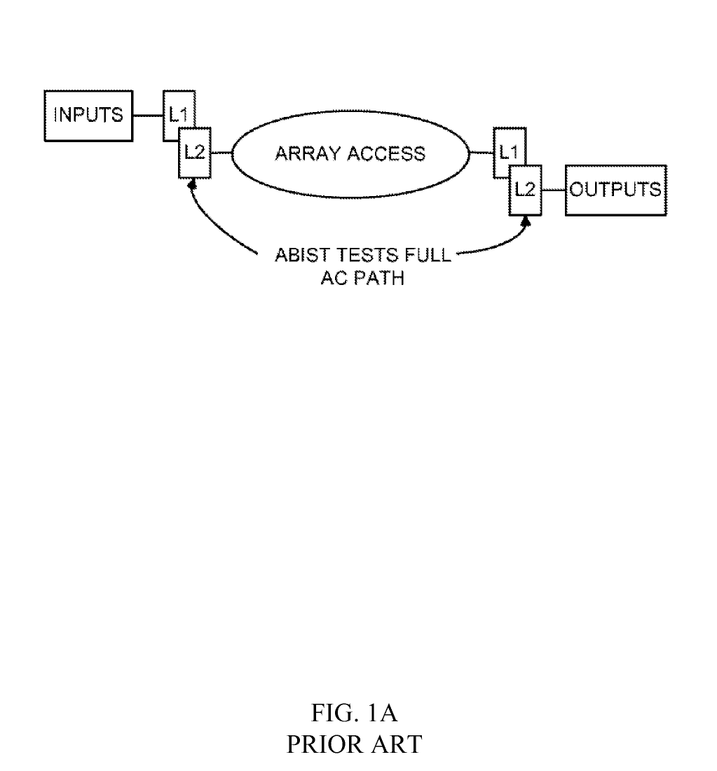

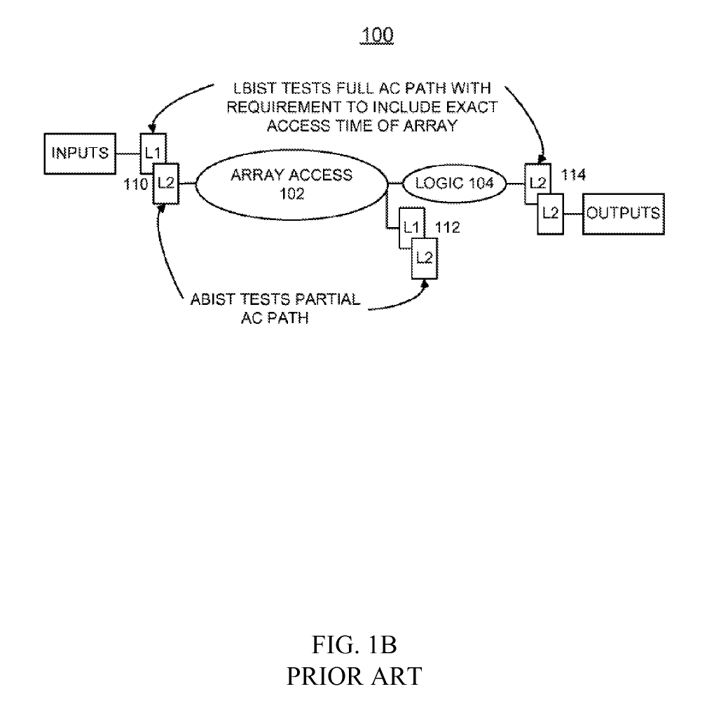

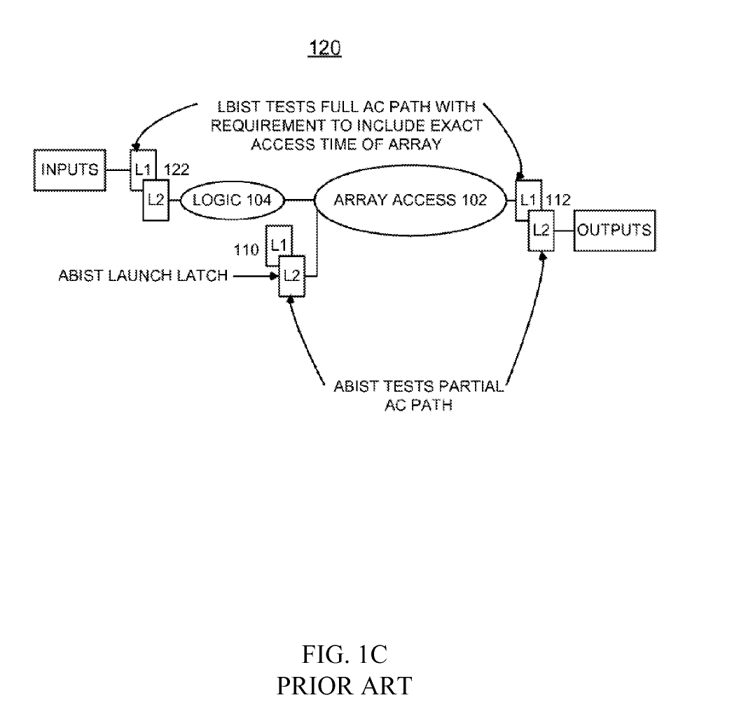

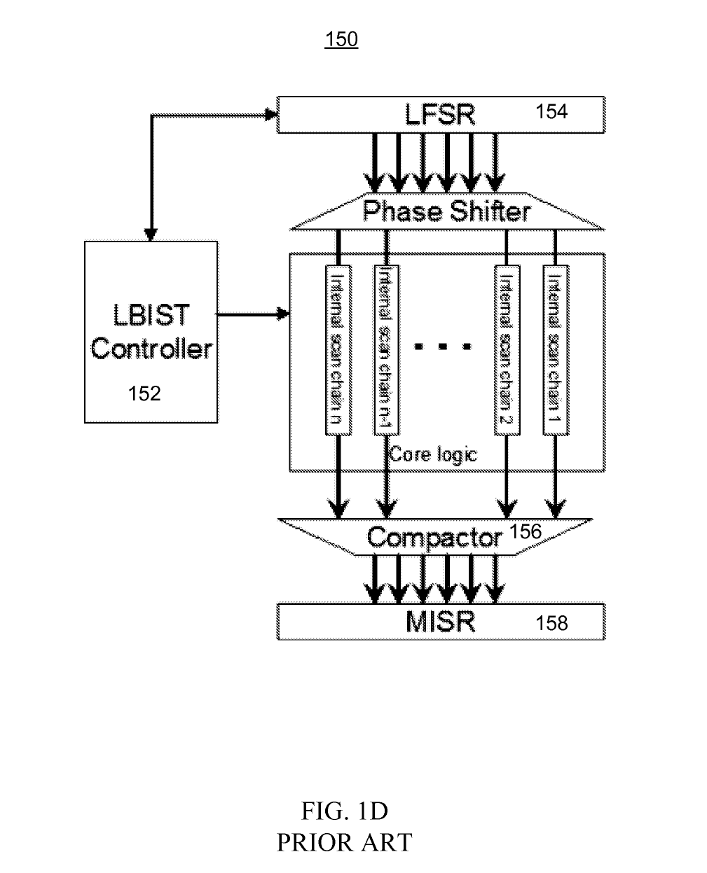

FIG. 1A illustrates a prior art circuit path for implementing ABIST testing techniques with a latch-bounded array. Latches exist at all the address and data input pins and latches exist at the data output pins. The array typically has one clock cycle to perform a read access and capture the data in the output latch. The data outputs would be launched out of the array on the subsequent cycle. ABIST testing of the arrays is straightforward when testing latch-bounded arrays. ABIST will test the entire path and if ABIST is run at system speed, AC defects will be caught.

Testing the full latch-to-latch paths for an array not latch-bounded may present other considerations. ABIST is not testing the full AC paths for arrays that are not latch-bounded since the logic in front of the array or downstream logic is not tested along with the array path. FIGS. 1B and 1C illustrate prior art circuit paths 100, 120 with arrays 102 and logic 104 where the paths are not a latch-bounded array as shown in FIG. 1A. Circuit path 100 includes an array 102 and downstream logic 104 shown in FIG. 1B. Circuit path 100 includes output latches 114 at the output of downstream logic 104 used with the array input latches 110 for LBIST testing the full AC latch-to-latch path 100. Circuit path 120 includes an array 102 and upstream logic 104 shown in FIG. 1C. Circuit path 120 includes input latches 122 at the input of upstream logic 104 used with the array output latches 112 for LBIST testing the full AC latch-to-latch path 120.

FIG. 1D illustrates a prior art high level diagram for an LBIST subsystem 150. An LBIST controller 152 may connect to a pattern generator. The pattern generator may be a Linear Feedback Shift Register (LFSR) design 154. It may incorporate a weighting function and other design techniques to create pseudo random patterns. The LBIST controller may control or work with a chip clocking mechanism to control scanning and functional operation of the chip. A compactor 156 may be included. A Multiple Input Signature Register (MISR) 158 may be used to capture values from scan chains for each LBIST test.

In accordance with aspects of the disclosure, an operation is provided testing a full AC latch-to-latch path that includes an array and logic. Aspects may include a clocking module and an addressing module which may exist as a part of a logic and array system separate from a data path. Aspects may include setting an address in the array to utilize to pass data through the array. Aspects may include configuring the clocking module to always fire every LBIST cycle. Aspects may include exact timing of reads and writes. Aspects may include forcing the array to read and write every cycle to a subset of addresses of an address space during LBIST. The subset of addresses may always be the same address. Aspects may show a two-port, double-pumped SRAM may take the form of a register of non-scan latches during LBIST. The use of one address to assist the test model in accurately predicting the data passing through the array may avoid random data and deter inefficiencies that may occur with typical latching. Aspects such as using a subset of addresses rather than an entire address space may make diagnostic tests efficient or effective compared to alternatives.

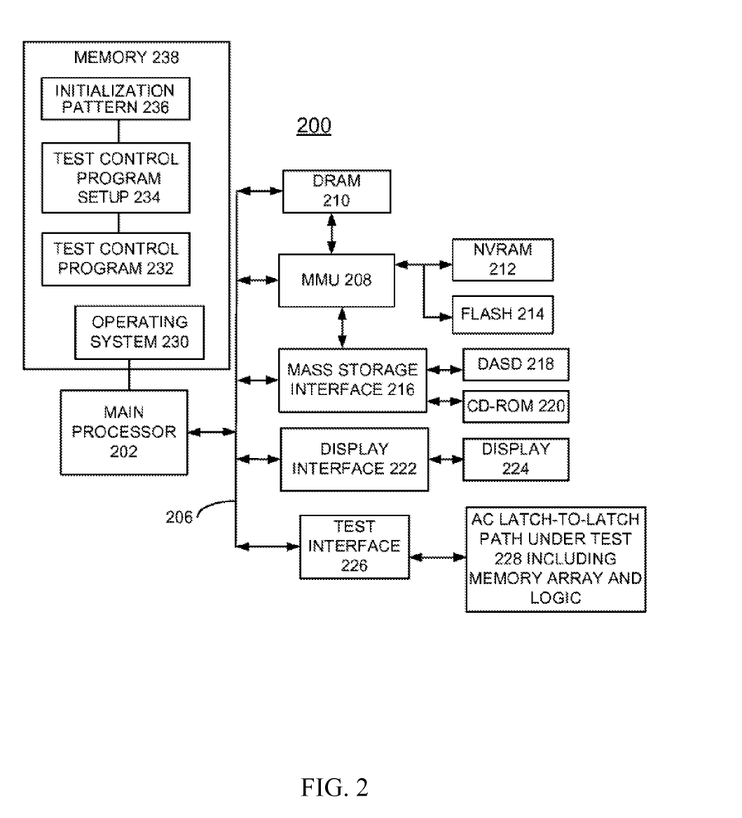

FIG. 2 shows an exemplary computer test system for implementing testing of circuit paths including arrays including LBIST diagnostics generally designated by the reference character 200 in accordance with an embodiment. Computer system 200 includes a main processor 202 or central processor unit (CPU) 202 coupled by a system bus 206 to a memory management unit (MMU) 208 and system memory including a dynamic random access memory (DRAM) 210, a nonvolatile random access memory (NVRAM) 212, and a flash memory 214. A mass storage interface 216 coupled to the system bus 206 and MMU 208 connects a direct access storage device (DASD) 218 and a CD-ROM drive 210 to the main processor 202. Computer system 200 includes a display interface 222 connected to a display 224, and a test interface 226 coupled to the system bus 206. An AC latch-to-latch path under test 228 including array and logic is coupled to the test interface 226. The AC latch-to-latch path under test 228 includes, for example, a test path as illustrated in FIGS. 1B and 1C. Computer system 200 includes an operating system 230, a test control program 232, a test control program setup 234, and an initialization pattern 236 of an embodiment that may be resident in a memory 238.

Computer test system 200 is shown in simplified form for understanding aspects of the disclosure. The illustrated computer test system 200 is not intended to imply architectural or functional limitations. Aspects of the disclosure can be used with various hardware implementations and systems and various other internal hardware devices, for example, multiple main processors.

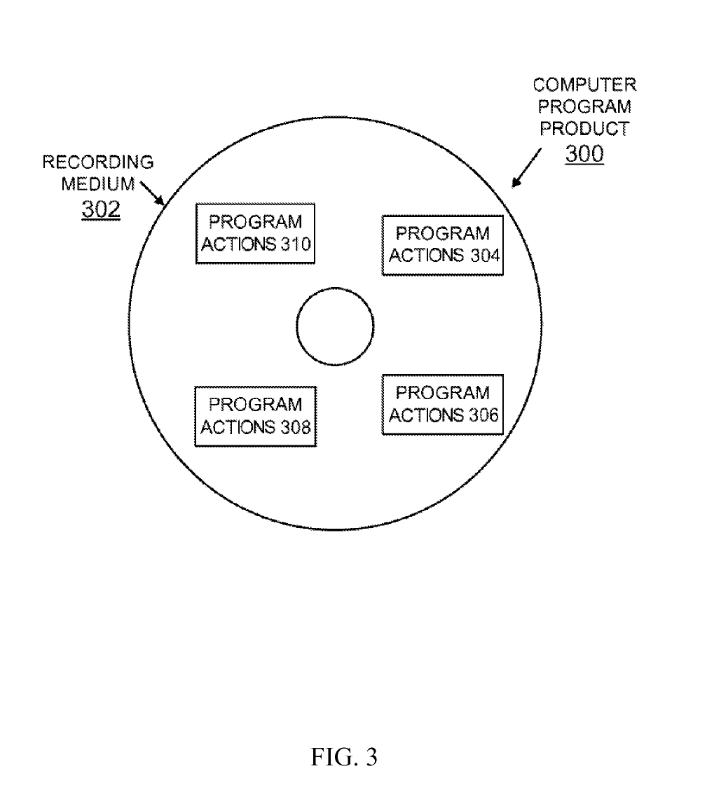

FIG. 3 illustrates an article of manufacture or a computer program product 300 according to aspects of the disclosure. The computer program product 300 includes a recording medium 302, such as, a floppy disk, a high capacity read only memory in the form of an optically read compact disk or CD-ROM, a tape, or another similar computer program product. Recording medium 302 stores program actions 304, 306, 308, 310 on the medium 302 for carrying out the methods for implementing testing of circuit paths including arrays including Logic Built in Self Test (LBIST) diagnostics of an embodiment in the system 200 of FIG. 2.

A sequence of program instructions or a logical assembly of one or more interrelated modules defined by the recorded program means 304, 306, 308, 310, direct the computer system 200 for implementing testing of circuit paths including arrays including Logic Built in Self Test (LBIST) diagnostics of an embodiment.

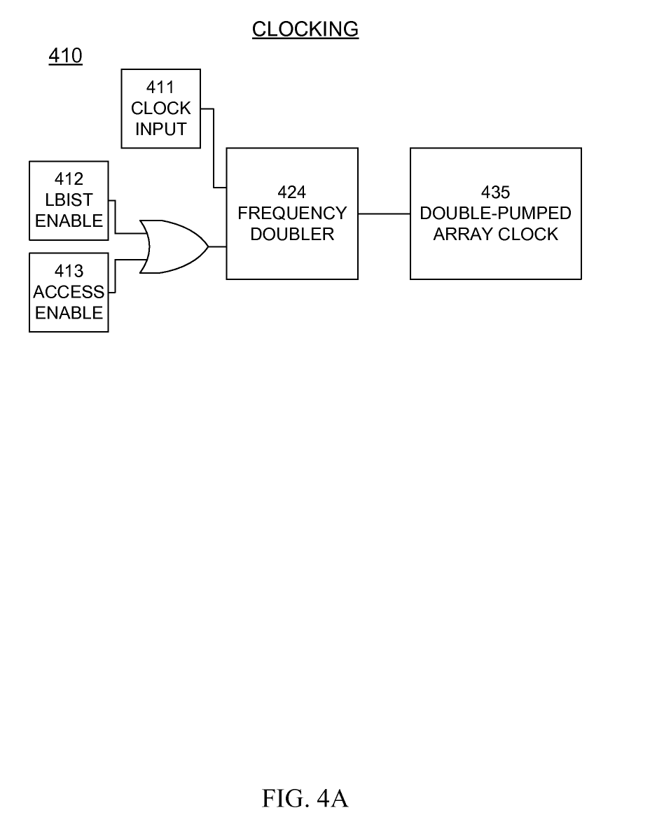

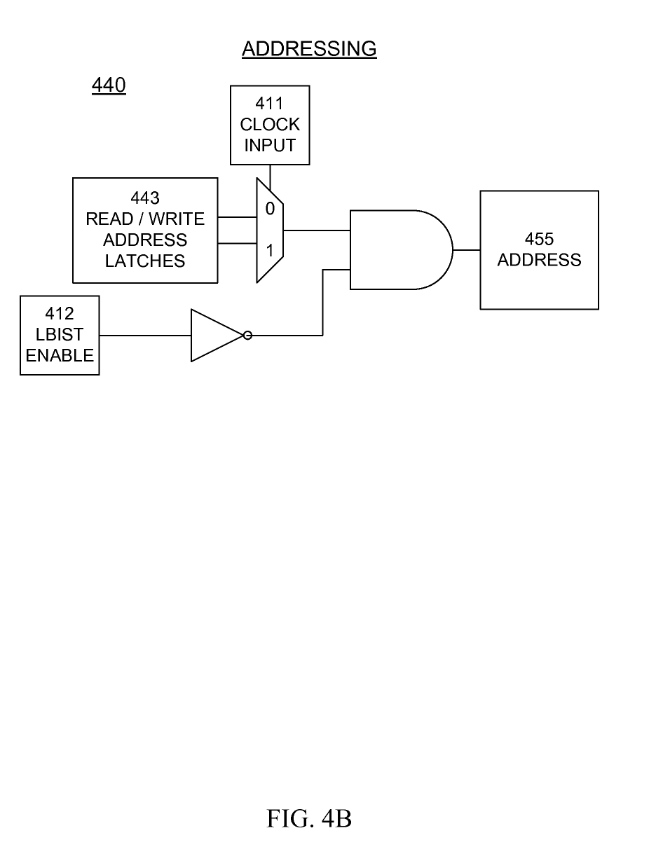

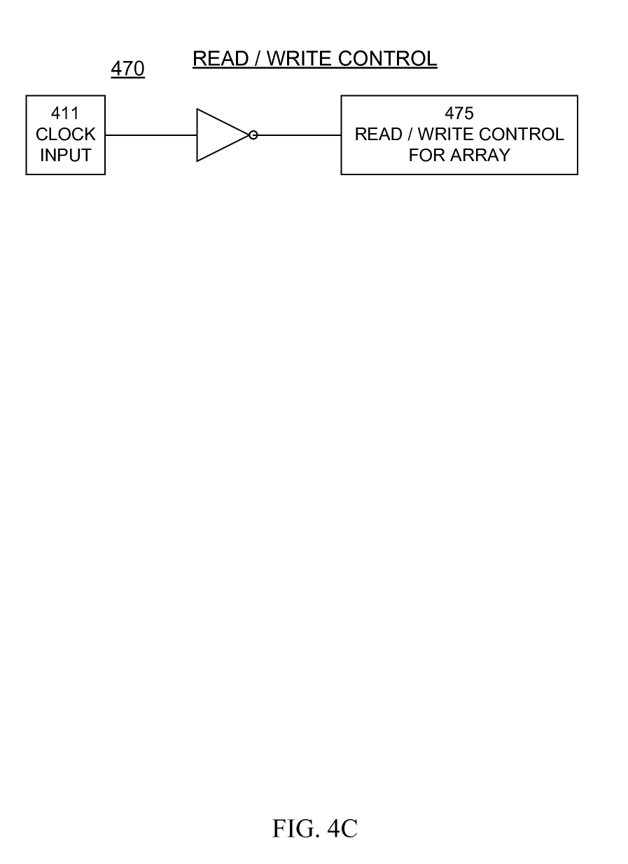

FIGS. 4A, 4B, and 4C depict diagrams illustrating exemplary clocking, addressing, and read/write control modules according to an embodiment. Clocking module 410 of FIG. 4A may force both a read clock pulse and a write clock pulse during LBIST. Using the clocking module 410 may facilitate the decoding of data or avoiding errors through suitable timing. A frequency doubler 424 may accept an input from a clock input 411. The frequency doubler 424 also may accept an input from a logic gate. The logic gate may be an OR gate running either an LIBST enable signal 412 or an access enable signal 413. The access enable signal 413 may include a read or a write. The result of the inputs from the clock input 411, the LBIST enable signal 412, and the access enable signal 413 to the frequency doubler 424 may produce a double-pumped array clock 435. The double-pumped array clock 435 may include the ability to force both a read clock pulse and a write clock pulse during LBIST.

Addressing module 440 of FIG. 4B may pass data to an address from a subset of an address space during LBIST mode. The address space may be all of the possible addresses for the array. Using a subset of the address space may facilitate the decoding of data compared to alternatives such as using a wide swath of random addresses. A multiplexer may accept an input from a clock input 411. The multiplexer may also accept an input from read/write address latches 443. ABIST may use the read/write address latches 443. A logic gate may accept an input from the multiplexer. The logic gate may be an AND gate. The AND gate may also accept an input from an inverter. The inverter may operate on the LBIST enable signal 412. The AND gate may produce an address 455. The address 455 may always be the same address during LBIST. In an embodiment, the address 455 may be an address consisting only of a set of a value of 0. For example, if the LBIST enable signal 412 is a value of 1, the inverter will invert the 1 to a 0. The input of the 0 into the AND gate may always produce an output of 0 to the address 455. Other embodiments may include other subsets of the address space. Such other embodiments may always set a value of 1 instead of 0 or may go back and forth between being 0 and being 1.

Read/write control module 470 of FIG. 4C may control reads and writes for an array. An inverter may invert the clock input signal 411. The inverted clock input signal 411 may produce read/write control for the array 475. This may enable exact timing of the reads and writes.

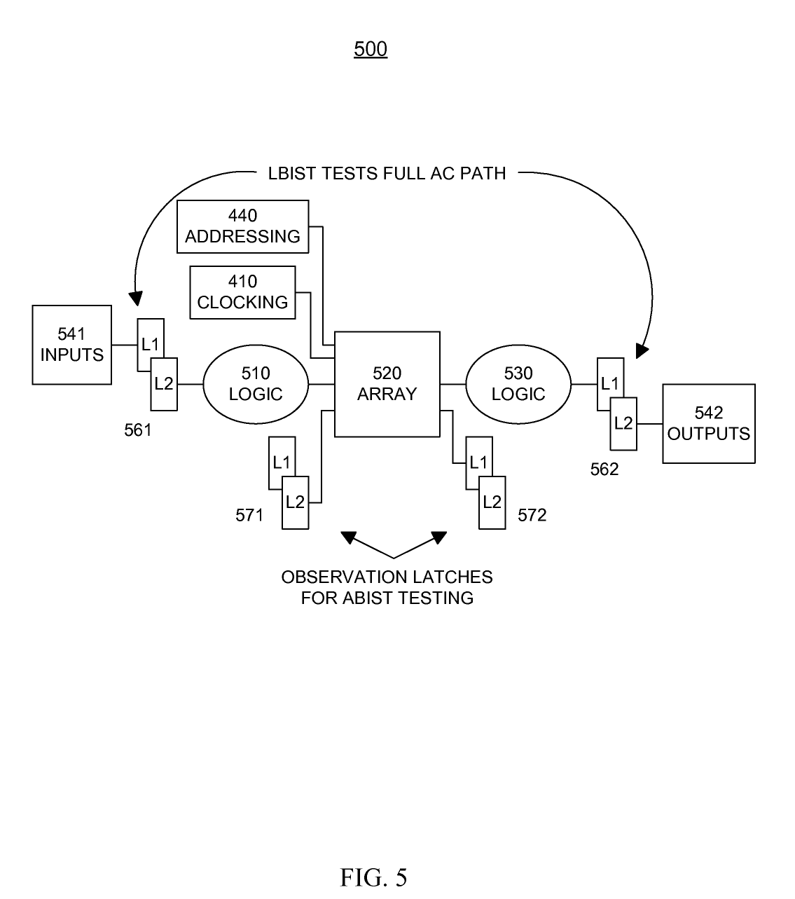

FIG. 5 depicts a logic and array system according to an embodiment. In accordance with aspects of the disclosure, an AC latch-to-latch path of a double-pumped memory array including logic may be diagnostically tested as shown by illustration 500. Latches 561 may exist at address and data input pins 541. Latches 562 may exist at data output pins 542. An upstream logic 510 or a downstream logic 530 may be combinational logic. LBIST may test the full AC path as upstream logic 510 and downstream logic 530 may be tested along the functional path of the array 520. Observation latches 571, 572 may exist for use in ABIST testing. The clocking module 410 and addressing module 440 may exist as a part of the logic and array system separate from a data path. The clocking module 410 and addressing module 440 may force the array 520 to read and write every cycle to a subset of addresses during LBIST. The subset of addresses may be one address. The subset of addresses may always be the same address. Aspects may assist the diagnostic test in avoiding random data which may be challenging to predict. Aspects may assist the diagnostic test in accurately predicting the data passing through the array.

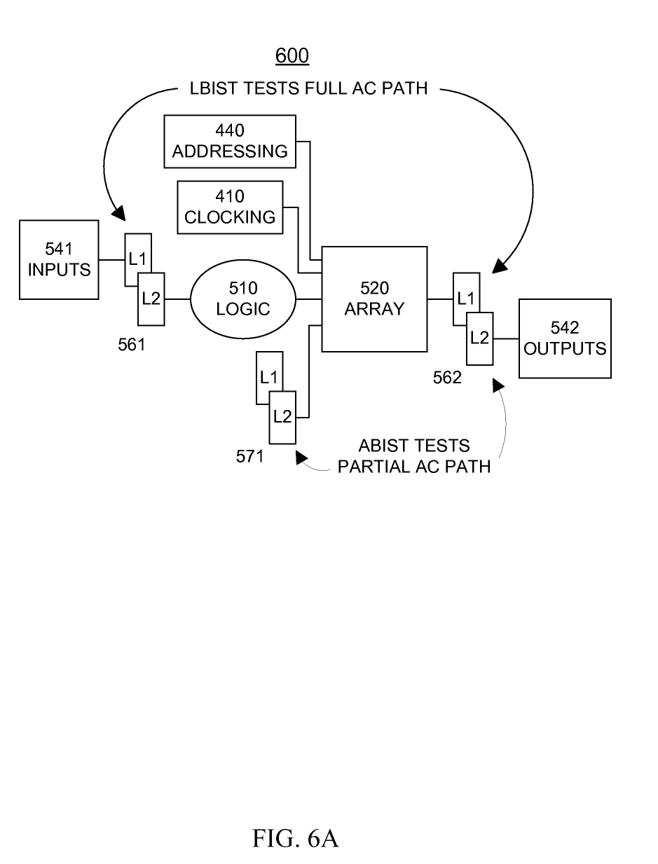

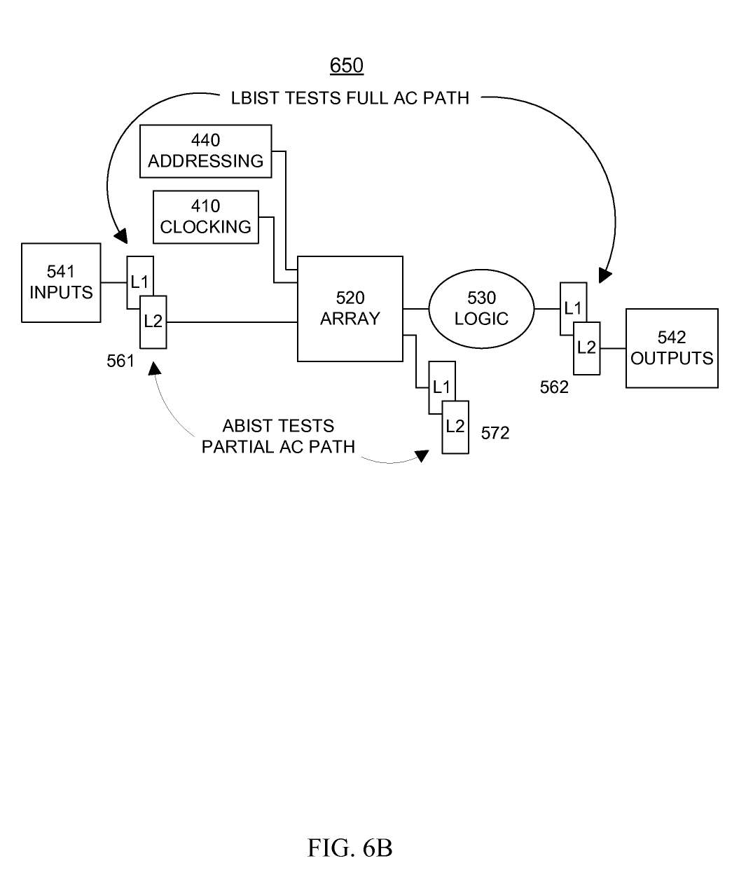

FIGS. 6A and 6B depict logic and array systems according to embodiments. Illustration 600 of FIG. 6A and illustration 650 of FIG. 6B are similar to illustration 500 except that illustration 500 includes both upstream and downstream logic as well as the corresponding observation latch for ABIST. Illustration 600 includes upstream logic 510 but not downstream logic 530. Illustration 650 includes downstream logic 530 but not upstream logic 510. Regardless, aspects of the disclosure may operate to successfully diagnostically test the full AC path in both illustration 600 and illustration 650.

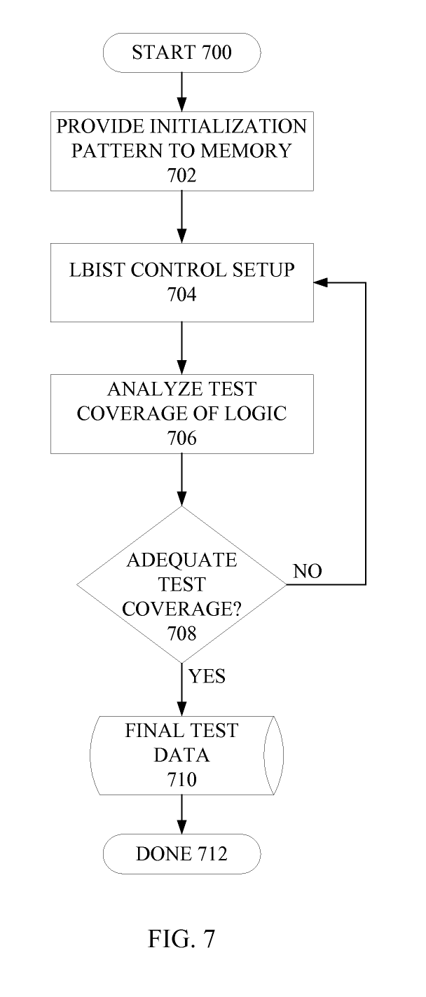

FIG. 7 is a flow chart illustrating exemplary phases for testing an array and logic including LBIST diagnostics in accordance with an embodiment starting at a block 700. An initialization pattern of memory is provided as indicated at a block 702. An LBIST control setup is provided at a block 704.

In an embodiment, the LBIST control setup provided at a block 704 may include the following illustrative aspects. An LBIST pin on an array macro may control logic. The logic may set a signal to enable LBIST. Aspects may provide that timing is directly determined. Aspects may fire a clock every LBIST clock cycle. Aspects may include the clocking module 410. During LBIST, the address latches for the array may be tied to an address. Running LBIST may force access to only one address of the array. The address may always be the same address. Aspects may include the addressing module 440. The array may perform a read and a write. Aspects may include the read/write control module 470. LBIST may perceive the data as a set of scan latches. An address of the array space may need initialization. In an embodiment, only one address of the array space may need initialization. The array may be used in real, functional mode. The paths used by LBIST may be functional paths. A standard layout or path-setup may be sufficient.

Initialization may be performed before running LBIST. Initialization may only need to be performed once. An ABIST engine may perform initialization. The ABIST engine may stop running upon placing a known value into an address that may be the same, or tied, for a read and a write. The array space may not need updating which otherwise may have been needed to update test weighting to increase test coverage. Adjusting LBIST settings may update test weighting to increase test coverage. Test coverage of the logic in the circuit path is analyzed with the provided initialization pattern of memory and LBIST control setup as indicated at a block 706.

LBIST may run under standard operating conditions without concern for the array. A test path may simulate a real, functional path. A functional path through the array may be used. It is determined whether adequate test coverage of the logic is provided as indicated at a decision block 708. Using the functional path through the array may yield appropriate, accurate coverage for launch out of the array to latches downstream. If inadequate test coverage is identified at decision block 708, then the LBIST control setup is updated as indicated at a block 704 and the sequential phases are repeated. If adequate test coverage is identified at decision block 708, then the final test data is provided as indicated at a block 710. Final test data may include a scan pattern, a functional pattern, or a combination pattern that is scan and functional. The final test data may make the array appear as a group of latches. Sequential phases are completed as indicated at a block 712.

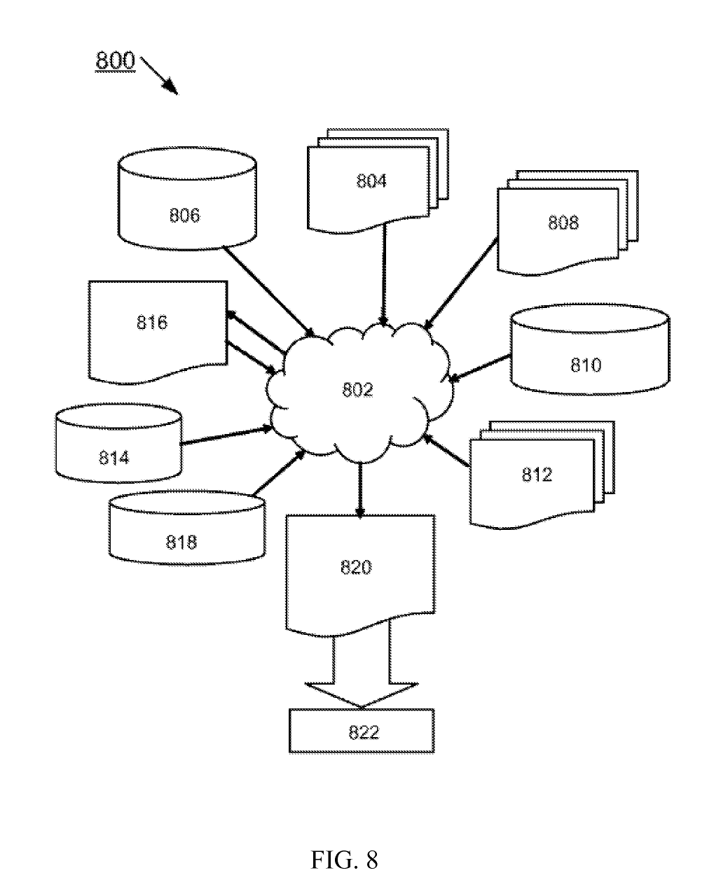

FIG. 8 shows a block diagram of an example design flow 800 according to aspects of the disclosure. Design flow 800 may vary depending on the type of integrated circuit being designed. For example, a design flow 800 for building an application specific integrated circuit (ASIC) may differ from a design flow 800 for designing a standard component. Design structure 804 is preferably an input to a design process 802 and may come from an IP provider, a core developer, or other design company or may be generated by the operator of the design flow, or from other sources. Design structure 804 includes circuits 200, 410, 440, 470, 500, 600, 650 in the form of schematics or HDL, a hardware-description language, for example, Verilog, VHDL, C, and the like. Design structure 804 may be contained on one or more machine readable medium. For example, design structure 804 may be a text file or a graphical representation of circuits 200, 410, 440, 470, 500, 600, 650. Design process 802 preferably synthesizes, or translates, circuits 200, 410, 440, 470, 500, 600, 650 into a netlist 806, where netlist 806 is, for example, a list of wires, transistors, logic gates, control circuits, I/O, models, etc. that describes the connections to other elements and circuits in an integrated circuit design and recorded on at least one of machine readable medium. This may be an iterative process in which netlist 806 is resynthesized one or more times depending on design specifications and parameters for the circuits.

Design process 802 may include using a variety of inputs; for example, inputs from library elements 808 which may house a set of commonly used elements, circuits, and devices, including models, layouts, and symbolic representations, for a given manufacturing technology, such as different technology nodes, 32 nm, 45 nm, 90 nm, and the like, design specifications 810, characterization data 812, verification data 814, design rules 816, and test data files 818, which may include test patterns and other testing information. Design process 802 may further include, for example, standard circuit design processes such as timing analysis, verification, design rule checking, place and route operations, and the like. One of ordinary skill in the art of integrated circuit design can appreciate the extent of possible electronic design automation tools and applications used in design process 802 without deviating from the scope and spirit of the invention. The design structure of the invention is not limited to any specific design flow.

Design process 802 preferably translates an embodiment of the disclosure as shown in FIGS. 1A-1D, 2, 3, 4A-4C, 5, 6A, and 6B along with any additional integrated circuit design or data (if applicable), into a second design structure 820. Design structure 820 resides on a storage medium in a data format used for the exchange of layout data of integrated circuits, for example, information stored in a GDSII (GDS2), GL1, OASIS, or any other suitable format for storing such design structures. Design structure 820 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 1A-1D, 2, 3, 4A-4C, 5, 6A, and 6B. Design structure 820 may then proceed to a stage 822 where, for example, design structure 820 proceeds to tapeout, is released to manufacturing, is released to a mask house, is sent to another design house, is sent back to the customer, and the like.

Embodiments other than as described may exist. The address to be used might be decided using an address counter stepping through addresses, a rotating shift register, or moving wordline by wordline circularly utilizing one value or bit. Such methods might include existence outside of the array macro.

What is claimed is:

1. A method for testing an array and logic, comprising:
providing an initialization pattern to an array in a logic and array system;
applying a diagnostic control setup wherein said setup includes firing a clock every diagnostic test clock cycle and selecting an address from a subset of an address space; and
running a diagnostic test of a combinational logic in the logic and array system;

2. The method of claim 1, wherein using a data path which is a functional path passing through the array in a functional mode.

3. The method of claim 1, wherein the address includes only one address.

4. The method of claim 1, wherein applying the diagnostic control setup includes a read and a write occurring every cycle during the diagnostic test.

5. The method of claim 1, wherein the diagnostic test is LBIST.

6. The method of claim 1, wherein running LBIST testing of the combinational logic in the logic and array system includes analyzing test coverage of the combinational logic.

7. The method of claim 6, further including updating the LBIST control setup responsive to inadequate test coverage of the combinational logic.

8. The method of claim 6, further including providing final test data responsive to adequate test coverage of the combinational logic.

9. The method of claim 1, wherein running LBIST testing of the combinational logic includes AC and DC testing of the combinational logic in the logic and array system.
